(19) United States
(12) Patent Application Publication
(10) Pub. No.: US 2025/0265396 A1
(43) Pub. Date: Aug. 21, 2025

(54) CHEMO-MECHANICAL CHANGE PREDICTIONS BY VOXEL BASED NUMERICAL SIMULATION ON OIL WELL CEMENT

(71) Applicant: SAUDI ARABIAN OIL COMPANY, Dhahran (SA)

(72) Inventors: Arpita P. BATHIJA, Houston, TX (US); Shannon EICHMANN, Katy, TX (US)

(73) Assignee: SAUDI ARABIAN OIL COMPANY, Dhahran (SA)

(21) Appl. No.: 18/444,851

(22) Filed: Feb. 19, 2024

(51) Int. Cl. G06F 30/28

(52) U.S. Cl. CPC G06F 30/28

(57) ABSTRACT

A chemo-mechanical change prediction system includes a characterization module operable to receive characterization information of a cement sample, a digital twin builder operable to receive 2D micro-CT data of a cement sample, the digital twin builder including an aggregator configured construct a 3D digital twin of the cement sample from the 2D micro-CT data and the characterization information. a DRP (digital rock physics) module operable to apply image-based computational techniques to the digital twin to segment various image components thereof into separate label fields for quantitative analysis, and an analyzer configured to determine chemo-mechanical changes in the cement sample due to exposure to carbon dioxide (CO2) and/or hydrogen (H2).

### FIELD OF THE DISCLOSURE

The present disclosure relates generally to cement used in oil wells and, more particularly, to the study of the link between chemical and physical properties of cement at the micro-pore scale.

### BACKGROUND OF THE DISCLOSURE

Cementing is a primary component of oil well drilling, operation, and abandonment. For instance, cement is injected into the annular space between an oil well casing and surrounding rock formations. Cement may also be used as one or more components of a plug used to seal a well during abandonment. Cement failure may result in leakage of one or more liquids from the producing or abandoned well and hence is a major cause of lost production and wellbore repair expenses. Cement plays a significant role by preventing leakage in storage and utilization of carbon dioxide (CO2) and hydrogen (H2). Chemical reactions with CO2 or H2 can change the pore system leading to changes in the mechanical properties of cement. Therefore, improved methods linking the chemical reactions to the mechanical properties are valuable before integrating the cement in or around a well in hydrogen or carbon capture, utilization, and storage (H2 or CCUS) wells.

With the advent of high performance computing, digital rock physics (DRP) has been used to model the effective properties of rocks. Digital rock physics is an image-based computational technique used to study the physical properties of rocks. This technique is based on numerical methods at pore scale.

### SUMMARY OF THE DISCLOSURE

Various details of the present disclosure are hereinafter summarized to provide a basic understanding. This summary is not an exhaustive overview of the disclosure and is neither intended to identify certain elements of the disclosure, nor to delineate the scope thereof. Rather, the primary purpose of this summary is to present some concepts of the disclosure in a simplified form prior to the more detailed description that is presented hereinafter.

According to an embodiment consistent with the present disclosure, a method for making chemo-mechanical change predictions in cement includes:
a) making a cement sample;
b) characterizing the cement sample using bulk analysis to generate characterization information of the cement sample;
c) performing a micro-CT scan of the cement sample to generate 2D micro-CT data;
d) using a processor to build a digital twin using the characterization information and 2D micro-CT data; and
e) exposing the cement sample to carbon dioxide (CO₂) and/or hydrogen (H₂);
f) repeating b)-d) to build an exposed digital twin; and
g) determining chemo-mechanical changes in the cement based on digital twin microstructural changes. . . .

In a further embodiment, a chemo-mechanical change prediction system includes a characterization module operable to receive characterization information of a cement sample, a digital twin builder operable to receive 2D micro-CT data of a cement sample, the digital twin builder including an aggregator configured construct a 3D digital twin of the cement sample from the 2D micro-CT data and the characterization information. a DRP (digital rock physics) module operable to apply image-based computational techniques to the digital twin to segment various image components thereof into separate label fields for quantitative analysis, and an analyzer configured to determine chemo-mechanical changes in the cement sample due to exposure to carbon dioxide (CO₂) and/or hydrogen (H₂).

In a further embodiment, a machine-readable storage medium having stored thereon a computer program for making chemo-mechanical change predictions in cement is disclosed. The computer program includes a routine of set instructions for causing the machine to perform the steps of:
a) obtaining characterization information that characterizes a cement sample based on bulk analysis;
b) building a digital twin using the characterization information and 2D micro-CT data of the cement sample;
c) repeating a)-b) to build an exposed digital twin; and p1 d) determining chemo-mechanical changes in the cement based on digital twin microstructural changes

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is a flow diagram of a method 100 for making determinations of chemo-mechanical changes in oil well cement, including for example predictions by voxel based numerical simulation in accordance with certain embodiments.

FIG. 2A is a view of a cylindrical cement sample.

FIG. 2B is a view of a digital twin comprising a 3D representation of a cement sample at the micro-scale in accordance with certain embodiments.

FIG. 3 is a block diagram of a chemo-mechanical change determination and prediction system in accordance with certain embodiments.

FIG. 4 is a block diagram of a computer system that may be used to implement one or more of the systems or methods described herein in accordance with certain embodiments.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments in accordance with the present disclosure generally relate to oil wells and, more particularly, to the study of the link between chemical and physical properties of cement at the micro-pore scale.

The disclosure herein elucidates the link between chemical and mechanical properties of cement. In certain embodiments, the effective cement properties of a digital twin prepared from micro-CT scan images are simulated using numerical methods in commercially available software, such as GeoDict™, based on physics and chemistry of cement research.

The use of digital rock physics (DRP) provides qualitative and quantitative understanding of the link between chemical and physical properties of cements at the micro-pore scale. DRP complements or completes infeasible and complex laboratory measurements, contributing not only detailed information but also new insights. In certain embodiments, higher speed and lower memory requirements are also achieved by artificial intelligence (AI) and/or machine learning (ML) algorithms.

The carbonation process of cement can be divided into two major steps: (1) the dissolution of the cement matrix by the acidic CO₂-rich fluid and (2) carbonate precipitation. Reaction (1) engenders water production and an increase of porosity whereas reaction (2) produces a reduction of porosity. These changes in porosity can be in the macro pores or the micro pores. Reaction with H₂ can produce totally different results than CO₂. The interplay of these chemical reactions and their effect on the pore system in the cement change the mechanical properties of the cement. Linking the microstructure changes due to the reactions to the mechanical property is an important approach to simplify this complex problem.

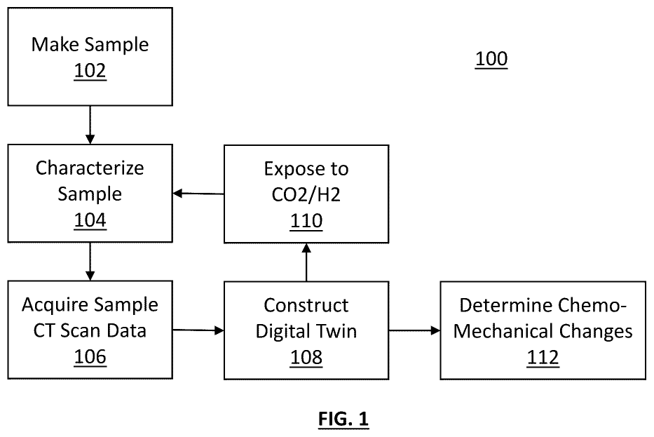

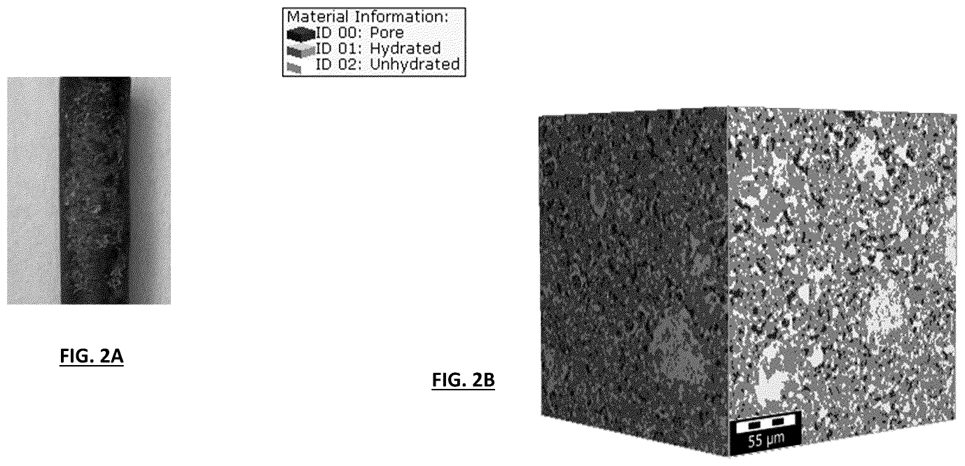

FIG. 1 is a flow diagram of a method 100 for making determinations of chemo-mechanical changes in oil well cement, including for example predictions by voxel based numerical simulation in accordance with certain embodiments. The method 100 can comprise, at a step 102, making one or more set cement samples. In one example embodiment, this accomplished by mixing cement with additives and then with water in a fixed ratio (such as 2:1), and casting it in a cylindrical mold. The mold may be cured at 180F and 3000 psi for 3 days. A cylindrical sample that may be 0.2″ D×0.5″ H for example is then cored from the set cement. FIG. 2A shows such a sample, for example made of class G cement.

At 104, bulk analysis techniques are used to characterize the cement sample, such as its composition, porosity, pore size distribution, and so on. Bulk analysis techniques can include for example. Bulk analysis techniques can include for instance X-Ray Diffraction (XRD), Mercury Injection capillary pressure (MICP), Scanning Electron Microscopy (SEM) and Gas Porosimetry.

At 106, a micro-CT scan of the sample is performed, and micro-Computed Tomography (CT) scan data of the sample is acquired. This 2D micro-CT scan data is then used, at 108, along with the bulk analysis information, to construct a 3D volume of the sample at high resolution, such as 0.5, 1, or 5 um/voxel, referred to as a “digital twin” of the cement under study. In constructing the digital twin of the cement, DRP (digital rock physics) is used, which is an image-based computational technique used to study the physical bulk properties of rocks and which may use commercially available software such as GeoDict™. The acquired CT information is used for complex material characterization, and the high resolution images of the material allow application of image processing methods to segment the various image components into separate label fields for quantitative analyses. FIG. 2B depicts a digital twin comprising a 3D representation of a cement sample at the micro-scale. Thus, the amount of the various components of the cement sample (i.e., mineral phases and porosity) can be identified and labeled as shown. Labeled images from image segmentation can be assigned physical properties of the known materials. The digital twin built from the high-resolution images captures the microstructural details of the real material and provides a data-driven “model” on which physical processes, such as elastic deformation using the basic laws of physics and numerical methods can be simulated. The mechanical properties of the digital twin can also be computed using commercially available software such as GeoDict™.

At 110, the cement is exposed to CO₂ and/or H₂ at various flow rates and/or durations. This can be performed at curing or after curing of the cement.

In certain embodiments, after exposure to CO₂ and/or H₂ at 110, flow of method 100 returns to the sample characterization at step 104, whereby bulk analysis techniques are used to characterize the exposed sample; a micro-CT scan of the exposed sample is performed (106); and a 3D volume (“digital twin”) is constructed (step 108) through application of DRP techniques as explained above. It may be convenient for purposes of this disclosure to refer to the digital twin constructed from the first, unexposed cement sample as the native digital twin, and to that constructed from the second, exposed sample as the exposed digital twin.

At 112, a determination of the chemo-mechanical changes in the cement due to the exposure to the CO₂ and/or H₂ is made. The determination is based on an analysis is conducted of the native and exposed digital twins, including observation of the microstructural changes like porosity changes in the cement due to exposure to CO₂ and/or H₂ at set durations, flow rates, cure states, etc. Observations and comparisons of the mechanical properties with and without CO₂ or H₂ are used to link the microstructural changes due to chemical reactions. They further permit quantification of the amount of mechanical property change to the microstructural changes to the CO₂ or H₂ flow rate and duration. An additional or alternative simulated exposure step 124 may be performed, whereby the digital twin may be exposed to CO₂ or H₂ digitally, using a reactive transport module of commercial software such as GeoDict™ to supplement the experimental determinations.

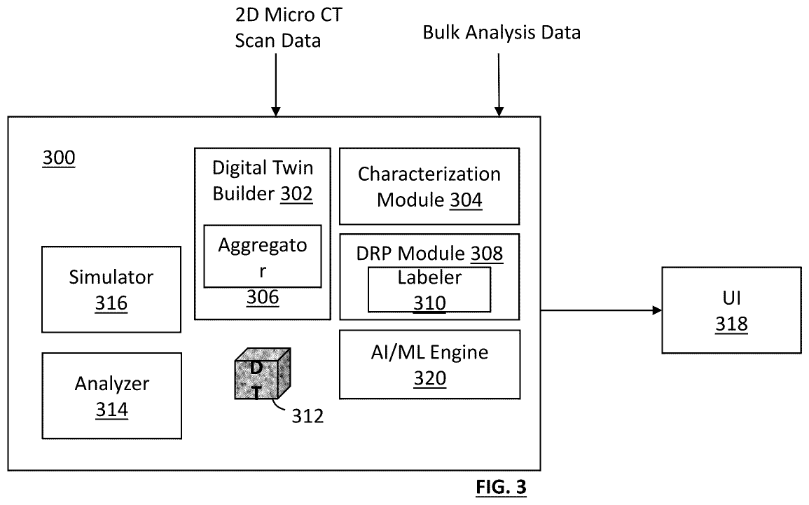

FIG. 3 is a block diagram of a chemo-mechanical change determination and prediction system 300 for elucidating the link between chemical and mechanical properties of oil well cement effected by exposure to CO₂ and/or H₂, for example by implementing one or more of the steps of method 100 described above. While, for purposes of simplicity of explanation, the steps of method 100 are shown and described as executing serially by system 300, it is to be understood and appreciated that the present examples are not limited by the illustrated order, as some actions could in other examples occur in different orders, multiple times and/or concurrently from that shown and described herein. Moreover, it is not necessary that all described actions be performed to implement the steps, and conversely, some actions may be performed that are omitted from the description.

System 300 includes a digital twin builder 302 operable to receive 2D micro-CT scan data of a cement sample obtained as described above, by mixing cement with additives and then with water in a fixed ratio (such as 2:1) and casting it in a cylindrical mold. The mold may be cured at 180F and 3000 psi for 3 days. The cylindrical sample that may be 0.2″ D×0.5″ H for example is then cored from the set cement, and is shown for example in FIG. 2A.

System 300 also includes a characterization module 304 operable to receive bulk analysis data of the cement sample to characterize for example its composition, porosity, pore size distribution, and so on, and provide the characterization information to digital twin builder 302.

Digital twin builder 302 includes an aggregator 306 configured to aggregate the 2D micro-CT scan data, and to use it along with the characterization information from the characterization module 304 to construct therefrom a digital twin 312 in the form of a 3D model of the cement sample at high resolution such as 0.5, 1, or 5 um/voxel.

A DRP module 308 is operable to apply image-based computational techniques used to study the physical bulk properties of rocks and allow the application of image processing methods to segment the various image components into separate label fields for quantitative analyses. Thus, the amount of the various components (i.e., mineral phases and porosity) can be labeled in this manner by labeler 310, and labeled images from image segmentation are assigned physical properties of the known materials of the cement sample. Labeler 310 acts on the constructed 3D model to generate the labeled digital twin 312, similar to that of FIG. 2B above, whereby microstructural details are captured in a data-driven model.

System 300 includes an analyzer 314 is used to make a determination of the chemo-mechanical changes in the cement due to the exposure to the CO₂ and/or H₂. The determination is based on an analysis conducted by the analyzer 314 of the native and exposed digital twins, including observation of the microstructural changes like porosity changes in the cement due to exposure to CO₂ and/or H₂ at set durations, flow rates, cure states, etc., as described above. Analyzer 314 can compare the mechanical properties represented by the native and exposed digital twins in order to link the microstructural changes due to chemical reactions. Analyzer 314 can quantify the amount of mechanical property change to the microstructural changes to the CO₂ or H₂ flow rate and duration.

System 300 can also include a simulator 316 to simulate physical processes, such as clastic deformation, using physics and numerical methods for example. The effects of exposure to CO₂ or H₂ can also be simulated and compared to those observed in the physical cement sample. In certain embodiments the cement can be exposed to CO₂ or H₂ digitally using a reactive transport module of commercial software, for example GeoDict™ to supplement the experimental and simulation data. Results can be provided to the analyzer 314 to analyze microstructural changes like porosity changes in the cement sample and in the digital twin 312 due to CO₂ or H₂ exposure at the curing stage or after curing and at various flow rates or durations, with the use of a user interface UI 318 presenting or displaying the results. Other simulation applications include numerical simulations to find clastic properties like modulus or deformation of the materials. Other applications can be to find the flow properties, filter properties, diffusion properties, conductive properties or acoustic properties. Different physical processes can be simulated on the digital twin 312 using different properties. For example, the study of the compaction of a porous sample using its deformed volume as well as changed porosity and many other property changes can be performed.

In certain embodiments, an artificial intelligence (AI)/machine learning (ML) engine 320 may be employed to achieve higher speed and lower memory requirements, for example at the simulation stage. Numerical simulations can be run with different solvers such as for example a fast Conjugate Gradient method or memory efficient-Neumann series solvers. AI can used to select the optimum solver. In addition, AI can be used at the segmentation stage to separate the various phases in the image.

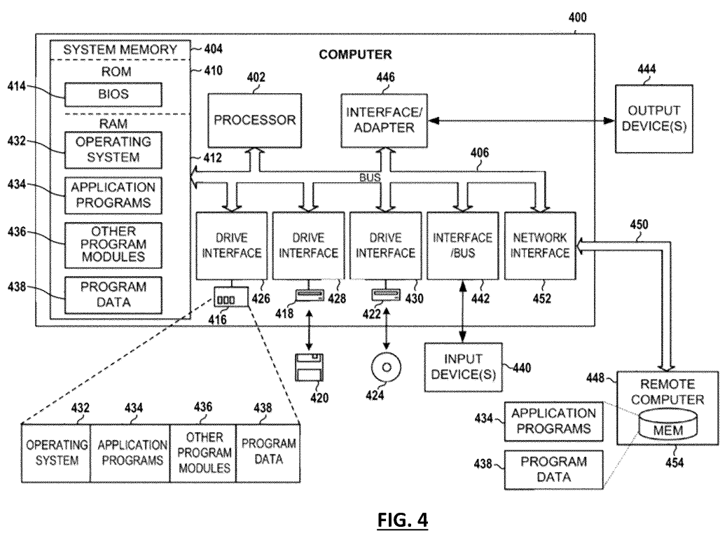

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 4. Furthermore, portions of the embodiments may be a computer program product on a computer-readable storage medium having computer readable program code on the medium. Any non-transitory, tangible storage media possessing structure may be utilized including, but not limited to, static and dynamic storage devices, volatile and non-volatile memories, hard disks, optical storage devices, and magnetic storage devices, but excludes any medium that is not eligible for patent protection under 35 U.S.C. § 101 (such as a propagating electrical or electromagnetic signals per se). As an example and not by way of limitation, computer-readable storage media may include a semiconductor-based circuit or device or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. A computer-readable non-transitory storage medium may be volatile, nonvolatile, or a combination of volatile and non-volatile, as appropriate.

Certain embodiments have also been described herein with reference to block illustrations of methods, systems, and computer program products. It will be understood that blocks and/or combinations of blocks in the illustrations, as well as methods of steps or acts or processes described herein, can be implemented by a computer program comprising a routine of set instructions stored in a machine-readable storage medium as described herein. These instructions may be provided to one or more processors of a general purpose computer, special purpose computer, or other programmable data processing apparatus (or a combination of devices and circuits) to produce a machine, such that the instructions of the machine, when executed by the processor, implement the functions specified in the block or blocks, or in the acts, steps, methods and processes described herein.

These processor-executable instructions may also be stored in computer-readable memory that can direct a computer or other programmable data processing apparatus to function in a particular manner, such that the instructions stored in the computer-readable memory result in an article of manufacture including instructions which implement the function specified. The computer program instructions may also be loaded onto a computer or other programmable data processing apparatus to cause a series of operational steps to be performed on the computer or other programmable apparatus to realize a computer implemented process such that the instructions which execute on the computer or other programmable apparatus provide steps for implementing the functions specified in flowchart blocks that may be described herein.

In this regard, FIG. 4 illustrates one example of a computer system 400 that can be employed to execute one or more embodiments of the present disclosure. Computer system 400 can be implemented on one or more general purpose networked computer systems, embedded computer systems, routers, switches, server devices. client devices, various intermediate devices/nodes or standalone computer systems. Additionally, computer system 400 can be implemented on various mobile clients such as, for example, a personal digital assistant (PDA), laptop computer, pager, and the like, provided it includes sufficient processing capabilities.

Computer system 400 includes processing unit 402. system memory 404, and system bus 406 that couples various system components, including the system memory 404, to processing unit 402. System memory 404 can include volatile (e.g. RAM, DRAM, SDRAM, Double Data Rate (DDR) RAM, etc.) and non-volatile (e.g. Flash. NAND, etc.) memory. Dual microprocessors and other multi-processor architectures also can be used as processing unit 402. System bus 406 may be any of several types of bus structure including a memory bus or memory controller, a peripheral bus, and a local bus using any of a variety of bus architectures. System memory 404 includes read only memory (ROM) 410 and random access memory (RAM) 412. A basic input/output system (BIOS) 414 can reside in ROM 410 containing the basic routines that help to transfer information among elements within computer system 400.

Computer system 400 can include a hard disk drive 416, magnetic disk drive 418, e.g., to read from or write to removable disk 420, and an optical disk drive 422, e.g., for reading CD. ROM disk 424 or to read from or write to other optical media. Hard disk drive 416, magnetic disk drive 418, and optical disk drive 422 are connected to system bus 406 by a hard disk drive interface 426, a magnetic disk drive interface 428, and an optical drive interface 430, respectively. The drives and associated computer-readable media provide nonvolatile storage of data, data structures, and computer-executable instructions for computer system 400. Although the description of computer-readable media above refers to a hard disk, a removable magnetic disk and a CD, other types of media that are readable by a computer, such as magnetic cassettes, flash memory cards. digital video disks and the like, in a variety of forms, may also be used in the operating environment: further, any such media may contain computer-executable instructions for implementing one or more parts of embodiments shown and described herein.

A number of program modules may be stored in drives and RAM 410, including operating system 432, one or more application programs 434, other program modules 436, and program data 438. In some examples, the application programs 434 can include digital twin builder 302, characterization module 304, aggregator 3-6, DRP module 308, labeler 310, and simulator 314. and the program data 438 can include digital twin 312 as well as the 2D micro CT data and bulk analysis data. The application programs 434 and program data 438 can include functions and methods programmed to make chemo-mechanical change predictions such as shown and described herein.

A user may enter commands and information into computer system 400 through one or more input devices 440, such as a pointing device (e.g., a mouse, touch screen), keyboard, microphone, joystick, game pad. scanner, and the like. These and other input devices 440 are often connected to processing unit 402 through a corresponding port interface 442 that is coupled to the system bus, but may be connected by other interfaces, such as a parallel port, serial port, or universal serial bus (USB). One or more output devices 444 (e.g., display, a monitor, printer, projector, or other type of displaying device) is also connected to system bus 406 via interface 446, such as a video adapter.

Computer system 400 may operate in a networked environment using logical connections to one or more remote computers, such as remote computer 448. Remote computer 448 may be a workstation, computer system, router, peer device, or other common network node, and typically includes many or all the elements described relative to computer system 400. The logical connections, schematically indicated at 450, can include a local area network (LAN) and/or a wide area network (WAN), or a combination of these, and can be in a cloud-type architecture, for example configured as private clouds, public clouds, hybrid clouds, and multi-clouds. When used in a LAN networking environment, computer system 400 can be connected to the local network through a network interface or adapter 452. When used in a WAN networking environment, computer system 400 can include a modem, or can be connected to a communications server on the LAN. The modem, which may be internal or external, can be connected to system bus 406 via an appropriate port interface. In a networked environment, application programs 434 or program data 438 depicted relative to computer system 400, or portions thereof, may be stored in a remote memory storage device 454.

Embodiments disclosed herein include:

A. A method for making chemo-mechanical change predictions in cement comprising:
a) making a cement sample;
b) characterizing the cement sample using bulk analysis to generate characterization information of the cement sample;
c) performing a micro-CT scan of the cement sample to generate 2D micro-CT data;
d) using a processor to build a digital twin using the characterization information and 2D micro-CT data; and
e) exposing the cement sample to carbon dioxide (CO₂) and/or hydrogen (H₂);
f) repeating b)-d) to build an exposed digital twin; and
g) determining chemo-mechanical changes in the cement based on digital twin microstructural changes.
   B. A chemo-mechanical change prediction system comprising:
a characterization module operable to receive characterization information of a cement sample;
a digital twin builder operable to receive 2D micro-CT data of a cement sample, the digital twin builder including an aggregator configured construct a 3D digital twin of the cement sample from the 2D micro-CT data and the characterization information;
a DRP (digital rock physics) module operable to apply image-based computational techniques to the digital twin to segment various image components thereof into separate label fields for quantitative analysis; and
an analyzer configured to determine chemo-mechanical changes in the cement sample due to exposure to carbon dioxide (CO₂) and/or hydrogen (H₂).
   C. A machine-readable storage medium having stored thereon a computer program for making chemo-mechanical change predictions in cement, the computer program comprising a routine of set instructions for causing the machine to perform the steps of:
a) obtaining characterization information that characterizes a cement sample based on bulk analysis;
b) building a digital twin using the characterization information and 2D micro-CT data of the cement sample;
c) repeating a)-b) to build an exposed digital twin; and
d) determining chemo-mechanical changes in the cement based on digital twin microstructural changes.

Each of embodiments A through C may have one or more of the following additional elements in any combination: Element 1: wherein the microstructural changes include porosity changes. Element 2: wherein determining chemo-mechanical changes comprises quantifying the amount of mechanical property change to the microstructural changes to carbon dioxide (CO₂) and hydrogen (H₂) flow rate and duration. Element 3: further comprising simulating exposure to carbon dioxide (CO₂) and hydrogen (H₂) using the digital twin. Element 4: wherein the digital twin comprises a 3D digital volume having a resolution of 0.5, 1, or 5 um/voxel. Element 5: wherein the bulk analysis techniques include one or more of X-Ray Diffraction (XRD), Mercury Injection capillary pressure (MICP), Scanning Electron Microscopy (SEM) and Gas Porosimetry. Element 6: further comprising conducting simulation to determine one or more of flow properties, filter properties, diffusion properties, conductive properties, acoustic properties, elastic properties, compaction properties, or porosity properties. Element 7: further comprising using artificial intelligence to select an optimum solver for the simulation.

By way of non-limiting example, exemplary combinations applicable to A through C include: Element 1 with Element 2; Element 1 with Element 3; Element 1 with Element 4; Element 1 with Element 5; Element 1 with Element 6; Element 1 with Element 7; Element 2 with Element 3; Element 2 with Element 4; Element 2 with Element 5; and Element 2 with Element 5. Element 2 with Element 7; Element 3 with Element 4; Element 3 with Element 5; Element 3 with Element 6; Element 3 with Element 7; Element 4 with Element 5; Element 4 with Element 6; Element 4 with Element 7; Element 5 with Element 6; Element 5 with Element 7; and Element 6 with Element7.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation used herein are merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third, etc.) is for distinction and not counting. For example, the use of “third” does not imply there must be a corresponding “first” or “second.” Also, if used herein, the terms “coupled” or “coupled to” or “connected” or “connected to” or “attached” or “attached to” may indicate establishing either a direct or indirect connection, and is not limited to either unless expressly referenced as such.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

The invention claimed is:

1. A method for making chemo-mechanical change predictions in cement comprising:
a) making a cement sample;
b) characterizing the cement sample using bulk analysis to generate characterization information of the cement sample;
c) performing a micro-CT scan of the cement sample to generate 2D micro-CT data;
d) using a processor to build a digital twin using the characterization information and 2D micro-CT data; and
e) exposing the cement sample to carbon dioxide (CO₂) and/or hydrogen (H₂);
f) repeating b)-d) to build an exposed digital twin; and
g) determining chemo-mechanical changes in the cement based on digital twin microstructural changes.

2. The method of claim 1, wherein the microstructural changes include porosity changes.

3. The method of claim 1, wherein determining chemo-mechanical changes comprises quantifying the amount of mechanical property change to the microstructural changes to carbon dioxide (CO₂) and hydrogen (H₂) flow rate and duration.

4. The method of claim 1, further comprising simulating exposure to carbon dioxide (CO₂) and hydrogen (H₂) using the digital twin.

5. The method of claim 1, wherein the digital twin comprises a 3D digital volume having a resolution of 0.5, 1, or 5 um/voxel.

6. The method of claim 1, wherein the bulk analysis techniques include one or more of X-Ray Diffraction (XRD), Mercury Injection capillary pressure (MICP), Scanning Electron Microscopy (SEM) and Gas Porosimetry.

7. The method of claim 1, further comprising conducting simulation to determine one or more of flow properties, filter properties, diffusion properties, conductive properties, acoustic properties, elastic properties, compaction properties, or porosity properties.

8. The method of claim 7, further comprising using artificial intelligence to select an optimum solver for the simulation.

9. A chemo-mechanical change prediction system comprising:
a characterization module operable to receive characterization information of a cement sample;
a digital twin builder operable to receive 2D micro-CT data of a cement sample, the digital twin builder including an aggregator configured construct a 3D digital twin of the cement sample from the 2D micro-CT data and the characterization information;
a DRP (digital rock physics) module operable to apply image-based computational techniques to the digital twin to segment various image components thereof into separate label fields for quantitative analysis; and
an analyzer configured to determine chemo-mechanical changes in the cement sample due to exposure to carbon dioxide (CO₂) and/or hydrogen (H₂).

10. The system of claim 9, further comprising:
a simulator operable to use the digital twin to simulate effects of exposure to carbon dioxide (CO₂) and/or hydrogen (H₂).

11. The system of claim 9, further including an AI/ML engine operable to accelerate simulation speed and/or reduce simulation memory requirements.

12. The system of claim 9, wherein the digital twin comprises a 3D digital volume having a resolution of 0.5, 1, or 5 um/voxel.

13. The system of claim 10, wherein the simulator is configured to determine one or more of flow properties, filter properties, diffusion properties, conductive properties, acoustic properties, elastic properties, compaction properties, or porosity properties.

14. The system of claim 13, further including an AI/ML engine operable to select an optimum solver for simulation by the simulator.

15. A machine-readable storage medium having stored thereon a computer program for making chemo-mechanical change predictions in cement, the computer program comprising a routine of set instructions for causing the machine to perform the steps of:
a) obtaining characterization information that characterizes a cement sample based on bulk analysis;
b) building a digital twin using the characterization information and 2D micro-CT data of the cement sample;
c) repeating a)-b) to build an exposed digital twin; and
d) determining chemo-mechanical changes in the cement based on digital twin microstructural changes.

16. The machine-readable storage medium of claim 15, wherein the microstructural changes include porosity changes.

17. The machine-readable storage medium of claim 15, wherein determining chemo-mechanical changes comprises quantifying the amount of mechanical property change to the microstructural changes to carbon dioxide (CO₂) and hydrogen (H₂) flow rate and duration.

18. The machine-readable storage medium of claim 15, the set of instructions further causing the machine to perform the step of:
simulating exposure to carbon dioxide (CO₂) and hydrogen (H₂) using the digital twin.

19. The machine-readable storage medium of claim 15, wherein the digital twin comprises a 3D digital volume having a resolution of 0.5, 1, or 5 um/voxel.

20. The machine-readable storage medium of claim 15, wherein the bulk analysis includes one or more of X-Ray Diffraction (XRD), Mercury Injection capillary pressure (MICP), Scanning Electron Microscopy (SEM) and Gas Porosimetry.
